(19) United States
(12) Patent Application Publication
(10) Pub. No.: US 2008/0258244 A1
(43) Pub. Date: Oct. 23, 2008

(54) SEMICONDUCTOR DEVICE

(75) Inventors: Masakazu GOTO, Kanagawa-ken (JP); Shigeru KAWANAKA, Kanagawa-ken (JP)

Correspondence Address: OBLON, SPIVAK, MCCLELLAND MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 12/016,412

(22) Filed: Jan. 18, 2008

(30) Foreign Application Priority Data
Jan. 18, 2007 (JP) 2007-008720

(51) Int. Cl. H01L 29/78

(52) U.S. Cl. 257/412; 257/E29.255

(57) ABSTRACT

In one aspect of the present invention, a semiconductor device may include a semiconductor substrate, a gate dielectric layer provided on the semiconductor substrate, a source region provided in the semiconductor substrate, a drain region provided in the semiconductor substrate, and a gate electrode provided on the gate dielectric layer having a metal containing layer and a polycrystalline silicon layer having an impurity ion, the polycrystalline silicon layer provided on the metal containing layer so as to cover an upper surface and side surface of the metal containing layer.

### CROSS REFERENCE TO RELATED APPLICATION

This application is based upon and claims the benefit of priority from Japanese Patent Application No. 2007-8720, filed on Jan. 18, 2007, the entire contents of which are incorporated herein by reference.

### BACKGROUND

A metal gate electrode is used as a gate electrode of a MISFET (Metal Insulator Semiconductor Field Effect Transistor). The metal gate is damaged by a chemical solution or oxidation ambient during manufacturing process. So in the conventional MISFET having a metal gate electrode, a protective sidewall such as an offset spacer is used. The offset spacer functions as a mask edge of for an ion implantation for forming a source/drain extension region.

However, in case the offset spacer is provided on the side surface of the metal gate for protecting the metal gate, the distance between the gate electrode and the source/drain extension is spaced and the on-current of the transistor is increased, when a heat treatment process with high temperature short time such as a millisecond anneal is used for activating impurity ion for forming the source/drain extension region.

### SUMMARY

Aspects of the invention relate to an improved semiconductor device.

In one aspect of the present invention, a semiconductor device may include a semiconductor substrate, a gate dielectric layer provided on the semiconductor substrate, a source region provided in the semiconductor substrate, a drain region provided in the semiconductor substrate, and a gate electrode provided on the gate dielectric layer having a metal containing layer and a polycrystalline silicon layer having an impurity ion, the polycrystalline silicon layer provided on the metal containing layer so as to cover an upper surface and side surface of the metal containing layer.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross sectional view of a semiconductor device in accordance with an embodiment of the present invention.

FIGS. 2A-2H are cross sectional views of the semiconductor device showing a manufacturing process of the embodiment.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### Embodiment

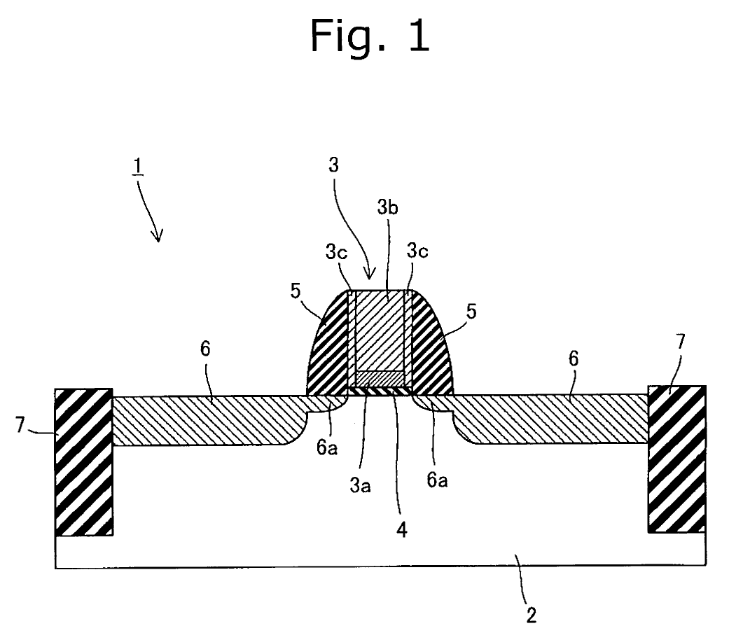

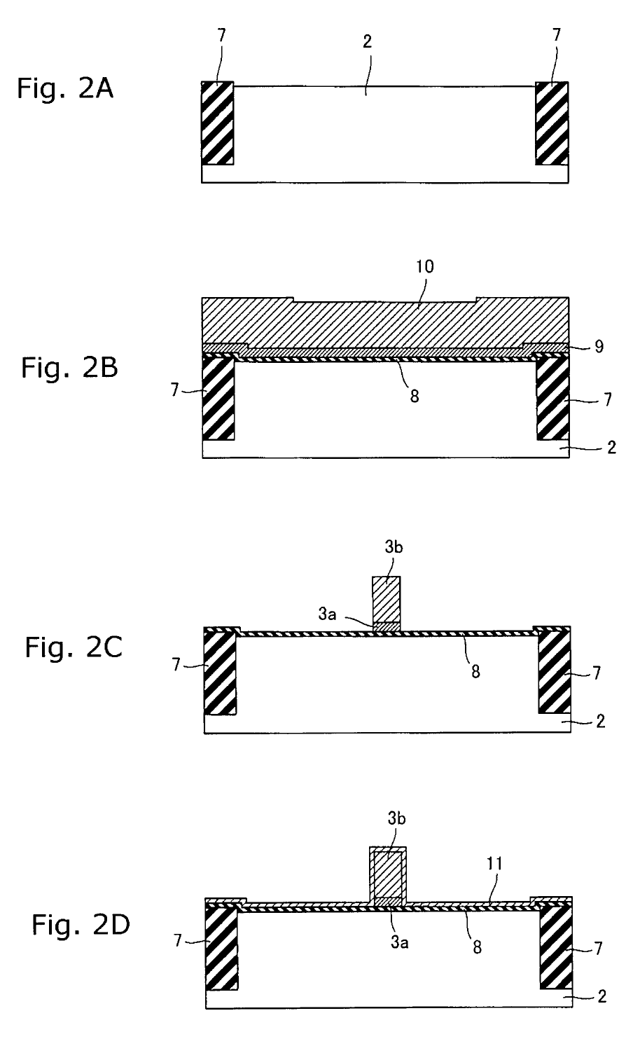

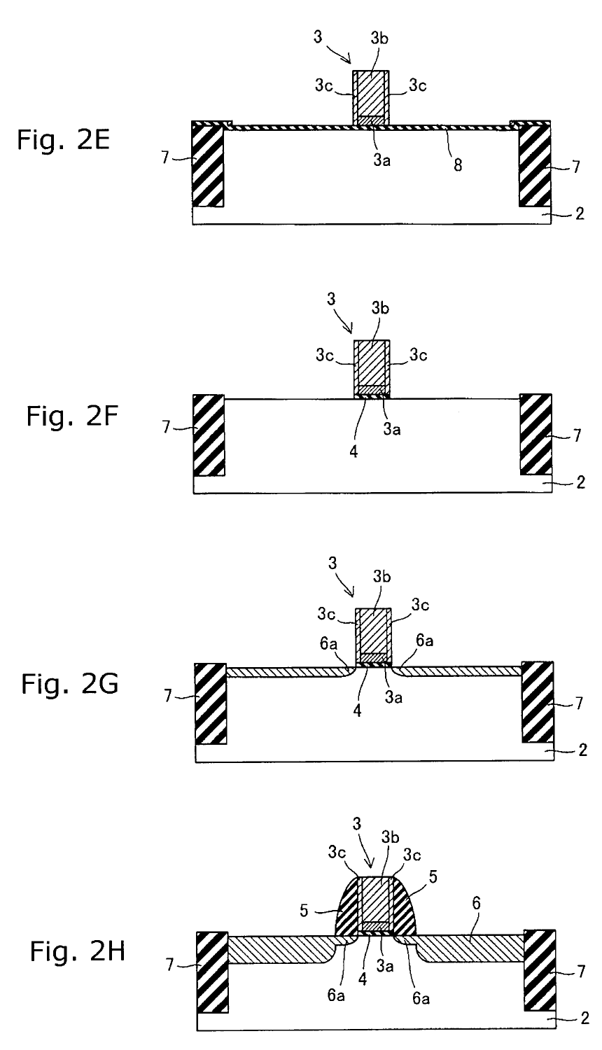

An embodiment of the present invention will be explained hereinafter with reference to FIGS. 1-2H.

FIG. 1 is a cross sectional view of a semiconductor device 1 in accordance with the embodiment.

In the semiconductor device 1, a gate electrode 3 provided on a semiconductor substrate 2 via a gate dielectric film 4, a gate sidewall (abbreviated as sidewall hereinafter) 5 provided on a side of the gate electrode 3 and on the semiconductor substrate 2, a source/drain region 6 provided in the semiconductor substrate 2 near a surface of the semiconductor substrate 2, and an isolation region 7 are provided. The source/drain region 6 includes an source/drain extension region 6a.

The gate electrode 3 includes a metal containing layer 3a provided on the gate dielectric film 4, a first polycrystalline layer 3b provided on the metal containing layer 3a and a second polycrystalline layer 3c provided on the gate dielectric film 4 and a side surface of the metal containing layer 3a and the first polycrystalline layer 3b. A silicide layer which is a composition of silicon and a metal such as Ni, Pt, Co, Er, NiPt, Co Ni or the like may be provided on the gate electrode 3.

The metal containing layer 3a is not depleted. The metal containing layer 3a is made of a metal such as W, Ta, Ti, Hf, Zr, Ru, Pt, Ir, Mo, Al or the like, or a full silicide having a metal such as W, Ta, Ti, Hf, Zr, Ru, Pt, Ir, Mo, Al or the like. The metal containing layer 3a may be made of a nitride, a carbide, or an oxide, which has a metal such as W, Ta, Ti, Hf, Zr, Ru, Pt, Ir, Mo, Al or the like. It may be preferable that the height (thickness) of the metal containing layer 3a is 1-20% of the height of the gate electrode 3, which is a sum of the height of the metal containing layer 3a and the first polycrystalline layer 3b. When the height of the metal containing layer 3a is less than 1% of the height of the gate electrode 3, it may be difficult to suppress the depletion of the gate electrode 3 sufficiently. When the height of the metal containing layer 3a is more than 20% of the height of the gate electrode 3, it may be difficult to reduce an oxidation, erosion by a chemical solution or a contamination of the gate electrode 3 sufficiently.

The first polycrystalline silicon layer 3b and the second polycrystalline layer 3c are made of a polycrystalline including an impurity ion. The first polycrystalline silicon layer 3b and the second polycrystalline layer 3c have an antioxidation and endurance to a chemical solution such as a sulfuric acid/hydrogen peroxide mixture or the like. The resistivity of polycrystalline silicon having an impurity ion is smaller than that of polycrystalline silicon not having an impurity ion. So the polycrystalline silicon having an impurity ion is suitable to be used as a part of the gate electrode. An n type impurity ion such as As, P or the like is used for a gate electrode of n type transistors, and a p type impurity ion such as B, Bf₂, In or the like is used for a gate electrode of n type transistors.

The gate dielectric layer 4 may be made of a SiO2, SiON, or a high dielectric constant material (high-k material; Hf based material such as HfSiON, HfSiO and HfO; Zr based material such as ZrSiON, ZrSiO, ZrO; Y based material Y₂O₃).

The sidewall 5 is made of, for example, a single layered SiN, a two layered structure having SiN and SiO₂ or a three layered structure.

The source/drain region 6 and the extension region 6a is formed by, for example, implanting a p type impurity ion such as B, BF2 or the like into the Si substrate 2 for p type transistors, and an n type impurity ion such as As, P or the like into the Si substrate 2 for n type transistors. A silicide layer having a metal such as a Ni, Pt, Co, Er, NiPt, CoNi or the like may be provided on the top surface of the source/drain region 6.

The isolation region 7 is made of a insulating material such as SiO₂, or the like and have a STI (Shallow Trench Isolation) structure.

Next a manufacturing process of the semiconductor device 1 as shown in FIG. 1 will be explained hereinafter with reference to FIGS. 2A-2H.

As shown in FIG. 2A, an isolation region 7 is formed in the semiconductor substrate 2. A well region (not shown ion FIG. 1) is formed by implanting an impurity ion into the semiconductor substrate 2. An n type impurity such as As, P or the like is implanted for a P type transistor, and a p type impurity such as B, Bf₂, In or the like is implanted for a N type transistor.

As shown in FIG. 2B, an insulating layer 8, a metal layer 9 and a first polycrystalline layer 10 are deposited on the semiconductor substrate 2 in this order. The insulating layer 8 is formed by a CVD (Chemical Vapor Deposition) method, an oxidation method, a plasma nitridation method or the like. The insulating layer 8 may be about 2.5-3.0 nm in thickness. The metal layer 9 is formed by a CVD method or the like. The metal layer 9 may be about 10 nm in thickness. The first polycrystalline layer 10 is formed by a CVD method or the like. The first polycrystalline layer 10 may be about 100 nm in thickness.

As shown in FIG. 2C, the first polycrystalline layer 10 and the metal layer 9 are patterned by using a photolithography and a RIE (Reactive Ion Etching) method. So the polycrystalline layer 3b and the metal containing layer 3a are provided.

As shown in FIG. 2D, a second polycrystalline layer 11 which has an impurity ion is provided on the entire exposed surface. Namely, the second polycrystalline layer 11 is provided on the top and side surface of the polycrystalline layer 3b, side surface of the metal containing layer 3a and a surface of the insulating layer 8. The second polycrystalline layer 11 may be no more than 5 nm. An n type impurity such as As, P or the like is implanted for an N type transistor, and a p type impurity such as B, Bf₂, In or the like is implanted for a P type transistor. It is preferable that the second polycrystalline layer 11 is formed with the impurity ion being added, since it may be difficult that the impurity ion is implanted into a portion of the second polycrystalline layer 11 provided on a side surface of the metal containing layer 3a and the first polycrystalline layer 3b.

As shown in FIG. 2E, the second polycrystalline layer 3c is formed on the side surface of the metal containing layer 3a and the first polycrystalline layer 3b. The second polycrystalline layer 3c is formed by removing a part of the polycrystalline layer 11 provided on the insulating layer 8 and a top surface of the first polycrystalline layer 3b. The second polycrystalline layer 3c covers the side surface of the metal containing layer 3a and the first polycrystalline layer 3b. So the gate electrode 3 which has the metal containing layer 3a, the first polycrystalline layer 3b and the second polycrystalline layer 3c is provided.

As shown in FIG. 2F, the gate dielectric layer 4 is formed by removing the insulating layer 8 with the first polycrystalline layer 3b and the second polycrystalline layer 3c as a mask. The insulating layer 8 is removed by etching using a hydrofluoric acid or the like. The metal containing layer 3a and the second polycrystalline layer 3c are provided on the gate dielectric layer 4.

In this process of forming the gate dielectric layer 4, the metal containing layer 3a is covered with the first polycrystalline layer 3b and the second polycrystalline layer 3c. The top surface of the metal containing layer 3a is covered with the first polycrystalline layer 3b. The side surface of the metal containing layer 3a is covered with the second polycrystalline layer 3c. Namely, the metal containing layer 3a is not exposed to the chemical solution. So the erosion of the metal containing layer 3a is reduced.

As shown in FIG. 2G, the source/drain extension region 6a is formed in the semiconductor substrate 2 by implanting impurity ion into the semiconductor substrate 2 with the gate electrode 3 as a mask. An n type impurity such as As, P or the like is implanted for an N type transistor, and a p type impurity such as B, Bf₂, In or the like is implanted for a P type transistor.

In case, a P type transistor and N type transistor are formed on a single semiconductor substrate, a photo resist is formed on the semiconductor substrate. In such case, the photo resist is removed by ashing or using chemical solution such as sulfuric acid and hydrogen peroxide, or the like. During removing resist process, the oxidation and erosion of the metal containing layer 3a is reduced, since the metal containing layer 3a is covered with the first polycrystalline layer 3a and the second polycrystalline layer 3b.

A heat treatment such as a millisecond anneal or the like is provided so as to activate the impurity ion in the source/drain extension region 6a with suppressing the diffusion of the impurity ion. In this process the top surface of the metal containing layer 3a and the side surface of the metal containing layer 3a are covered with the first polycrystalline layer 3b and the second polycrystalline layer 3c. So even if the gate electrode 3 is in contact with the manufacturing apparatus during heating, the metal in the metal containing layer 3a is not diffused and moved to the manufacturing apparatus, since the metal containing layer 3a is not exposed to outside.

As shown in FIG. 2H, the sidewall 5 is formed on the semiconductor substrate 2 and on the side surface of the gate electrode 3. Later that, the source/drain region 6 is formed by implanting an impurity ion into the semiconductor substrate 2 with the sidewall 5 as a mask edge. The impurity of the source/drain region 6 is the same conductivity type as the source/drain extension region 6a. The impurity is implanted to the first polycrystalline layer 3b.

In case, a P type transistor and N type transistor are formed on a single semiconductor substrate, a photo resist is formed on the semiconductor substrate. In such case, the photo resist is removed by ashing or using chemical solution such as sulfuric acid and hydrogen peroxide, or the like. During removing resist process, the oxidation and erosion of the metal containing layer 3a is reduced, since the metal containing layer 3a is covered with the first polycrystalline layer 3a, the second polycrystalline layer 3b and the sidewall 5.

A heat treatment such as a millisecond anneal or the like is provided so as to activate the impurity ion in the source/drain region 6 with suppressing the diffusion of the impurity ion. In this process the top surface of the metal containing layer 3a and the side surface of the metal containing layer 3a are covered with the first polycrystalline layer 3b, the second polycrystalline layer 3c and sidewall 5. So even if the gate electrode 3 is in contact with the manufacturing apparatus during heating, the metal in the metal containing layer 3a is not diffused and moved to the manufacturing apparatus, since the metal containing layer 3a is not exposed to outside.

The on-current of the transistor in the embodiment is not reduced, since the distance between the gate electrode 3 and the source/drain extension 6a is not so spaced with comparing to a conventional transistor having a protective sidewall such as an offset spacer on a side surface of the gate electrode. Furthermore, the oxidation and erosion of the metal containing layer 3a during a manufacturing process may be reduced.

The metal in the metal containing layer 3a is not diffused to a manufacturing apparatus especially during heating, since the top surface of the metal containing layer 3a is covered with the first polycrystalline layer 3b. So the contamination of the chamber from the metal containing layer in the gate electrode may be reduced.

Embodiment of the invention has been described with reference to the examples. However, the invention is not limited thereto.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device, comprising:
a semiconductor substrate;
a gate dielectric layer provided on the semiconductor substrate;
a source region provided in the semiconductor substrate;
a drain region provided in the semiconductor substrate; and
a gate electrode provided on the gate dielectric layer having a metal containing layer and a polycrystalline silicon layer having an impurity ion, the polycrystalline silicon layer provided on the metal containing layer so as to cover an upper surface and side surface of the metal containing layer.

2. A semiconductor device of claim 1, wherein the polycrystalline silicon layer includes a first polycrystalline silicon layer which is provided on the upper surface of the metal containing layer and a second polycrystalline silicon layer which is provided on the side surface of the metal containing layer.

3. A semiconductor device of claim 2, wherein the second polycrystalline silicon layer is provided on the gate dielectric layer.

4. A semiconductor device of claim 2, wherein the second polycrystalline silicon layer is provided on a side surface of the first polycrystalline silicon layer.

5. A semiconductor device of claim 3, wherein the second polycrystalline silicon layer is provided on a side surface of the first polycrystalline silicon layer.

6. A semiconductor device of claim 1, wherein the metal containing layer has at least one of W, Ta, Ti, Hf, Zr, Ru Pt, Ir, Mo, and Al.

7. A semiconductor device of claim 1, wherein a side surface of the metal containing layer is covered with the polycrystalline silicon layer.

8. A semiconductor device of claim 1, wherein an upper surface of the metal containing layer is covered with the polycrystalline silicon layer.

9. A semiconductor device of claim 1, wherein an upper surface and side surface of the metal containing layer is covered with the polycrystalline silicon layer.

10. A semiconductor device of claim 2, wherein an upper surface and side surface of the metal containing layer is covered with the polycrystalline silicon layer.

11. A semiconductor device of claim 3, wherein an upper surface and side surface of the metal containing layer is covered with the polycrystalline silicon layer.
